(19) United States
(12) Patent Application Publication
(10) Pub. No.: US 2021/0303758 A1
(43) Pub. Date: Sep. 30, 2021

(54) Accelerated Hardware Using Dual Quaternions

(71) Applicant: Ultraleap Limited, Bristol (GB)

(72) Inventor: Benjamin John Oliver Long, Bristol (GB)

(21) Appl. No.: 17/212,774

(22) Filed: Mar. 25, 2021

Related U.S. Application Data
(60) Provisional application No. 63/003,152, filed on Mar. 31, 2020.

(51) Int. Cl. G06F 30/20; G06F 9/38; G06F 9/30

(52) U.S. Cl. CPC G06F 30/20; G06F 9/30036; G06F 9/3885; G06F 9/3869

(57) ABSTRACT

Techniques for concatenating, interpolating and upsampling pose transforms represented as dual quaternions are described, including: (1) derivation of a complex-valued matrix form of dual quaternions and dual quaternion operations; (2) derivation of a transformation operator on position vectors which obviates an explicit conversion to a classical 4×4 spatial transformation matrix and keeps results in complex-valued matrix space; (3) design for a generic lookup table system for functions to supply logarithm and exponentiations of the dual quaternion in its native format with trigonometry lookup tables to avoid precision issues when denominators tend to zero; and (4) a mechanism for wrapping the complex-exponentiation together with a simple complex arithmetic unit for computing dual quaternion macro-operations in both native dual quaternion space and through simplifications of the equivalent complex-valued matrix to compute dual quaternion operations such as inverses, multiplications, logarithms and exponentials in order to chain the pose transformations encoded within.

### PRIOR APPLICATION

This application claims the benefit of U.S. Provisional Patent Application No. 63/003, 152, filed Mar. 31, 2020, which is incorporated by reference in its entirety.

### FIELD OF THE DISCLOSURE

The present disclosure relates generally to improved techniques in hardware design using transforms represented as dual quaternions.

### BACKGROUND

The tracking of spatial systems is difficult to achieve, since for any given system there is a cost and also no best way to track general things. These spatial systems may require tracking involving many different sensors. Since they are tracking independently, they may not sample synchronously. They may sample at uneven intervals based on differing compute times, differing hardware implementations and across potentially many discrete processing systems. Synchronizing and synthesizing a consistent spatial model of the world across all of these is necessary in many fields such as logistics, robotics, autonomous vehicles and any technology that requires positioning modelled objects in space.

Moreover, there is no good hardware implementation of the tools required to manipulate and curate the transform data that is created by one or more tracking systems, as it is generally achieved with a software-based methodology. In this disclosure, an efficient example of such an implementation is derived and described.

The solid mechanics of rigid bodies is a model of the physical world that can be described using rigid pose transformations, which contain both a rotational component and a translational component. As such these are important building blocks for creating spatial models of real-world systems, which include model building for tracking systems of various kinds. However, manipulating transformations is difficult, as can be attested by the wealth of literature on different methods to achieve this. The “gold standard” in manipulating and resampling pose transformations seems to (by consensus) be using a dual quaternion representation, as an extension of the ‘real’ quaternions which are an efficient method of describing rotation-only transformations. Extending the methods of quaternions which are rotation-only to create dual quaternion method is not straightforward and the state-of-the-art work that exists is in a state unsuitable for transcription into a hardware implementation. A set of techniques for concatenating, interpolating and upsampling pose transforms represented as dual quaternions is therefore herein described.

### SUMMARY

Using a complex-valued matrix form of dual quaternions it is possible to derive dual quaternion operations that are more computationally efficient than traditional methods. Also it is possible to derive transformation operator on position vectors that obviates the need for an explicit conversion to a classical 4×4 spatial transformation matrix before application. In addition, it is possible to use a novel design for a generic lookup table system for functions to supply the more complex operations with analytic function data. The resulting hardware implementation is a complex-exponentiation together with a simple complex arithmetic unit for computing dual quaternion macro-operations. This results in both native dual quaternion space and a complex-value space for ease of implementation without compromising efficiency.

By taking these steps and assembling the machine or functional unit described quaternions and dual quaternions may be efficiently operated on in a space that utilizes the available hardware subcomponents. This is especially useful in computing interpolations of single or chained transformations. These single or chained transformations may be produced by tracking systems of any kind. Resampling or up-sampling is necessary to achieve high accuracy when combining data sets or multiple approximations of position from multiple sensors whereby each yield a different reference frame as a coordinate system that this invention may be used to interpolate between. A specific use case is recognizable in the situation where a machine learning inference network generates reference frame transformations too slowly to be useful in a particular application or use case. In this situation, up-sampling using this method is a worthwhile approach to generating a continuous data stream that satisfies higher-level system constraints.

In summary, the novel steps that have been accomplished herein are: (1) the derivation of a complex-valued matrix form of dual quaternions and dual quaternion operations; (2) the derivation of a transformation operator on position vectors which obviates the need for an explicit conversion to a classical 4×4 spatial transformation matrix and keeps the result in the complex-valued matrix space; (3) the design for a generic lookup table system for functions to supply the logarithm and exponentiations of the dual quaternion in its native format with trigonometry lookup tables to avoid precision issues when denominators tend to zero; and (4) a mechanism for wrapping the complex-exponentiation together with a simple complex arithmetic unit for computing dual quaternion macro-operations in both native dual quaternion space and through simplifications of the equivalent complex-valued matrix to compute dual quaternion operations such as inverses, multiplications, logarithms and exponentials in order to chain the pose transformations encoded within.

### BRIEF DESCRIPTION OF THE DRAWINGS

The accompanying figures, where like reference numerals refer to identical or functionally similar elements throughout the separate views, together with the detailed description below, are incorporated in and form part of the specification, serve to further illustrate embodiments of concepts that include the claimed invention and explain various principles and advantages of those embodiments.

FIG. 1 shows a graph of a first trigonometric function for developing a ‘shallow’ pipeline unit.

FIG. 2 shows a graph of a second trigonometric function for developing a ‘shallow’ pipeline unit.

FIG. 3 shows a graph of a third trigonometric function for developing a ‘shallow’ pipeline unit.

FIG. 4 shows a graph of a fourth trigonometric function for developing a ‘shallow’ pipeline unit.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

I. Algebraic Underpinnings

Cayley-Dickson algebras are the algebras accessible via the Cayley-Dickson construction. The Cayley-Dickson construction involves taking each 2ⁿ⁻¹-dimensional algebra, adding a further imaginary component which effectively forms a 2ⁿ-dimensional algebra with elements described as ordered pairs of the 2ⁿ⁻¹-dimensional elements. In this way, complex numbers (2-dimensional) are ordered pairs of real numbers, quaternions (4-dimensional) are ordered pairs of complex numbers and so on. As more rounds of the Cayley-Dickson construction are applied, the resulting algebras lose operational symmetries and become harder to manipulate.

The Cayley-Dickson construction is valid so long as the square of each new imaginary component is −1. However, alternative algebras can be produced if when the final step is taken the square of the imaginary component is chosen to be otherwise. Further application of the Cayley-Dickson construction applied to these algebras is then invalid, but the algebras themselves are still meaningful. If the square of the final imaginary component is chosen to be −1, the Cayley-Dickson construction can continue as normal, if 0 is chosen then the resulting algebra is known as a ‘dual’ algebra and if 1 is chosen then the resulting algebra is known as a ‘split’ algebra.

While quaternions (4-dimensional) in particular enjoy popularity because they have composition properties that make them isomorphic to rotation transforms, less popularized is the idea that the dual quaternions (8-dimensional) have composition properties that make them isomorphic to all pose transforms or reference frames, that is transformations which consist of only a rotational and a translational component.

As the Cayley-Dickson construction can be viewed as ordered pairs of elements, then the encoding of components can be reimagined as matrices, so for example complex numbers are represented as pairs of real numbers, which implies:

$$( a + i b ) [ \begin{matrix}1 \\ i\end{matrix} ] = [ \begin{matrix}+ a + ib \\ - b + ia\end{matrix} ] = [ \begin{matrix}a & b \\ - b & a\end{matrix} ] [ \begin{matrix}1 \\ i\end{matrix} ] .$$

Similarly, one can define a 4×4 matrix for a quaternion a +ib+jc+kd containing each of the basis components 1, i, j and k. However, for quaternions, the reality of the Cayley-Dickson construction (that a quaternion is expressible as an ordered pair of complex numbers) implies that a different construction for the matrix representation may also be pursued:

a+ib+jc+kd=a+ib+(c+id)j,

so an equivalent matrix to quaternions may be constructed as:

$$a + i b + ( c + i d ) j [ \begin{matrix}1 \\ j\end{matrix} ] = [ \begin{matrix}+ a + ib + ( c + id ) j \\ - c + di + ( a - ib ) j\end{matrix} ] = [ \begin{matrix}a + b i & c + d i \\ - c + d i & a - b i\end{matrix} ] [ \begin{matrix}1 \\ j\end{matrix} ] ,$$

because the basis matrix multiplication must be applied from the left and obey the anticommutativity rules. A dual quaternion may be written as:

a+bi+cj+dk+(e+fi+gj+hk)ε,

where ε²=0. For this disclosure, the following formulation on the dual quaternion may be used:

$$a + b i + ( c + d i ) j + ( e + f i + ( g + h i ) j ) ϵ [ \begin{matrix}1 \\ j \\ ϵ \\ j ϵ\end{matrix} ] ,$$

then expanding the initial stages it can be written that this is equivalent to:

$$[ \begin{matrix}a + bi + ( c + di ) j + ( e + fi + ( g + hi ) j ) ϵ \\ - c + di + ( a - bi ) j + ( - g + hi + ( e - fi ) j ) ϵ \\ 0 + 0 i + ( 0 + 0 i ) j + ( a + bi + ( c + di ) j ) ϵ \\ 0 + 0 i + ( 0 + 0 i ) j + ( - c + di + ( a - bi ) j ) ϵ\end{matrix} ]$$

which can be expanded to a 4×4 matrix of complex numbers:

$$[ \begin{matrix}a + bi & c + di & e + fi & g + hi \\ - c + di & a - bi & - g + hi & e - fi \\ 0 & 0 & a + bi & c + di \\ 0 & 0 & - c + di & a - bi\end{matrix} ]$$

Crucially, the complex numbers do not split up, suggesting that they (a+bi, c+di, etc.) may be treated indivisibly and that any manipulation involving dual quaternions can be expressed as an equivalent using similar operators by acting on 4-dimensional vectors or 4×4 matrices of complex numbers.

In a similar way, this may also be split into an equivalent set of 8-dimensional vectors or 8×8 matrices of real numbers.

Using the above complex-valued matrix form of dual quaternions, it is possible to derive dual quaternion operations that are more computationally efficient than traditional methods. Included below is a derivation of a transformation operator on position vectors which obviates the need for an explicit conversion to a classical 4×4 spatial transformation matrix and keeps the result in the complex-valued matrix space. In addition, a novel design may be used for a generic lookup table system for functions to supply the logarithm and exponentiations of the dual quaternion in its native format with trigonometry lookup tables and avoid precision issues when denominators tend to zero. Lastly, this disclosure enables a mechanism for wrapping the complex-exponentiation together with a simple complex arithmetic unit for computing dual quaternion macro-operations in both native dual quaternion space and through simplifications of the equivalent complex-valued matrix. This will compute dual quaternion operations such as inverses, multiplications, logarithms and exponentials in order to chain the pose transformations encoded within.

II. Dual Quaternion Operations

Performing operations on dual quaternions can be used to perform operations on the underlying transformations. For instance, in a similar way to quaternion representations that encode only rotations and 4×4 real-valued spatial transformation matrices, dual quaternions may be composed right-to-left to concatenate a set of pose transforms together.

Smooth, minimal movement interpolation of pose transforms, which is difficult to describe or compute in other spaces (such as the classical 4×4 spatial transformation matrix that is the most common representation of transformations of this type) has a particularly simple form in dual quaternions that mimics linear interpolation. Given a dual quaternion that is composed of two ordered quaternions,

r=p+qε,

the linear interpolation of the pose transforms or reference frames that starts at r₀=P₀+q₀ε and ends at r₁=Pₜ+q₁ε with the interpolation variable r in the interval [0, 1] yields:

r_{τ, linear}=r₀(r₀⁻¹r₁)^{τ,}

r_{τ, linear}=r₀ exp(τln(r₀⁻¹r₁)), 0

p_{τ}+q_{τ}ε=(p₀+q₀ε)exp(τln(p₀⁻¹(1−q₀⁻¹p₀ε))).

It is also possible to compute a cubic interpolation equivalent. Defining four quaternions or dual quaternions r₋₁, r₀, r₁ and r₂ over which to compute the interpolation, it can be written:

r_{τ, cubic}=r_{τ, linear} exp(2τ(1−τ) ln(r_{τ, linear} ⁻¹a_{τ, linear})),

where:

a_{τ, linear}a ₀ exp(τln(a ₀⁻¹a₁)),

and each aₜ is described by:

aₜ=rₜ exp(−¼(ln(rₜ⁻¹rₜ₊₁)+ln(rₜ⁻¹rₜ₋₁))).

III. Transposing Operations into Matrices

The key operations described by the dual quaternion construct may be transferred over to the matrix representation with fewer changes than would be necessary if the dual quaternion space were used. In the same way that classically, a pose transformation consisting of a rotation and translation component are transformed and encoded into a dual quaternion for more effective processing when that processing is unavailable in initial encoding of the information, the dual quaternion can be transformed into a complex-valued matrix representation when the processing would be otherwise less effective in the domain of the dual quaternion algebra. However, in this case, there appears to be an exact isomorphism of each operation in the complex-valued matrix representation.

Considering each of the required operation in turn, multiplying the complex-valued matrices which describe the dual quaternion which in turn embody the transformations is equivalent to the dual quaternion product. Inverting this matrix is equivalent to a dual quaternion inverse.

This even remains true when considering the matrix logarithm and matrix exponential. Computing the logarithm or exponential of the matrix is equivalent to computing the logarithm or exponential of the underlying dual quaternion (and should not be confused with taking the logarithm or exponentiation of the standard 4×4 spatial transformation matrix which is sometimes used as an approximation to blending operations on pose transforms). In this way, operations that are more efficient to compute in dual quaternion space may be achieved in that way, whereas operations deemed more efficient in the space described by the complex- or real-valued matrix definition may be achieved there.

In the special case of applying the transformation held in the dual quaternion to a direction or position vector, traditionally this is applied by transforming the dual quaternion encoding of the post transform into a standard 4×4 spatial transformation matrix before application to the direction or position vector. Here it is shown that this is unnecessary, as once the direction or position vector is encoded into a quaternion—as is standard practice in plain quaternion rotations—this may also be described as a permutation on the matrix operation. But in the case of the position vector there is no obvious equivalent operation in the original dual quaternion space. The operation for a direction vector (with input matrix r encoding the vector components xᵣ, yᵣ, zᵣ and output matrix r′ encoding the vector components xᵣ′, yᵣ′, zᵣ′) is given by applying the real quaternion portion of the dual quaternion, a+bi+cj+dk+(e+fi+gj+hk)ε in the usual manner of a quaternion rotation:

$$\begin{matrix}{r}^{′} = {f}_{r} ( {x}_{r}^{′} , {y}_{r}^{′} , {z}_{r}^{′} ) \\ = [ \begin{matrix}0 + {x}_{r}^{′} i & {y}_{r}^{′} + {z}_{r}^{′} i \\ - {y}_{r}^{′} + {z}_{r}^{′} i & 0 - {x}_{r}^{′} i\end{matrix} ] , \\ = [ \begin{matrix}a + b i & c + d i \\ - c + d i & a - b i\end{matrix} ] [ \begin{matrix}0 + {x}_{r} i & {y}_{r} + {z}_{r} i \\ - {y}_{r} + {z}_{r} i & 0 - {x}_{r} i\end{matrix} ] \\ [ \begin{matrix}a - bi & - c - di \\ c - di & a + bi\end{matrix} ] ,\end{matrix}$$

while the operation for a position vector is given by the same quaternion product but with the quaternion product of a+bi+cj+dk and −e+fi+gj+hk added (which applies the translation), which may be represented by the complex-valued matrices (with input matrix p encoding the vector components xₚ, yₚ, zₚ and output matrix p′ encoding the vector components xₚ′, yₚ′, Zₚ′):

$$\begin{matrix}{p}^{′} = {f}_{r} ( {x}_{p}^{′} , {y}_{p}^{′} , {z}_{p}^{′} ) + [ \begin{matrix}a + bi & c + di \\ - c + di & a - bi\end{matrix} ] [ \begin{matrix}- e + fi & g + hi \\ - g + hi & - e - fi\end{matrix} ] , \\ = {f}_{p} ( {x}_{p}^{′} , {y}_{p}^{′} , {z}_{p}^{′} ) [ \begin{matrix}0 + {x}_{p}^{′} i & {y}_{p}^{′} + {z}_{p}^{′} i \\ - {y}_{p}^{′} + {z}_{p}^{′} i & 0 - {x}_{p}^{′} i\end{matrix} ] .\end{matrix}$$

IV. Dual Quaternion Logarithm and Exponential

As the complex-valued matrix form of the logarithm and exponential is more complicated than considering the logarithm and exponential of the quaternion or dual quaternion itself, opting to implement these particular operations directly is a more efficient approach.

Methods to derive the logarithm and exponential for the quaternion and dual quaternion may be obtained through the Taylor expansion of each function and the principle of analytic continuity. For brevity, instead quaternion logarithms and exponentials are taken as given, expanded with dual numbers and then simplified using identities for dual numbers. The required identities for dual numbers may be readily obtained from Taylor expansions, which terminate after the first term because ε².

The exponential of the quatemion p=a+bi+cj+dk is:

$$θ = \sqrt{{b}^{2} + {c}^{2} + {d}^{2}} , \\ {e}^{p} = {e}^{a} ( \frac{sin θ}{θ} ( b i + c j + d k ) + cos θ ) ,$$

and the logarithm of the quaternion is:

$$m = \sqrt{{a}^{2} + {b}^{2} + {c}^{2} + {d}^{2}} , \\ n = \sqrt{{b}^{2} + {c}^{2} + {d}^{2}} , \\ θ = a tan 2 ( n , a ) = {tan}^{- 1} \frac{n}{a} , \\ ln p = ln m + \frac{θ}{n} ( b i + c j + d k ) .$$

By substituting a dual number for each of the four scalar quaternion components in the logarithm and exponentiation the equivalent dual quaternion operation can be determined. For the dual quatemion r=p+qε, exponentiation is:

$$\tilde{θ} = \sqrt{{( b + f ϵ )}^{2} + {( c + g ϵ )}^{2} + {( d + h ϵ )}^{2}} , \\ {e}^{p + q ϵ} = {e}^{a + e ϵ} ( \frac{sin \tilde{θ}}{\tilde{θ}} ( ( b + f ϵ ) i + ( c + g ϵ ) j + ( d + h ϵ ) k ) + cos \tilde{θ} ) ,$$

but the square root of a dual number expands to:

$$\sqrt{α + βϵ} = \sqrt{α} + ϵ \frac{β}{2 \sqrt{α}} .$$

The dual valued angle \tilde{θ} then expands to:

$$\sqrt{{b}^{2} + {c}^{2} + {d}^{2} + ( 2 b f + 2 c g + 2 d h ) ϵ} = \sqrt{{b}^{2} + {c}^{2} + {d}^{2}} + \frac{b f + c g + d h}{\sqrt{{b}^{2} + {c}^{2} + {d}^{2}}} ϵ , \\ θ = \sqrt{{b}^{2} + {c}^{2} + {d}^{2}} , \\ γ = bf + c g + d h , \\ \tilde{θ} = θ + \frac{γ}{θ} ϵ .$$

Expanding the trigonometry functions sin \tilde{θ} and cos \tilde{θ}:

$$s = sin θ = sin θ + ϵ \frac{γ}{θ} cos θ , \\ c = cos \tilde{θ} = cos θ - ϵ \frac{γ}{θ} sin θ ,$$

and:

e^{a+eε}=^{a}εe^{a}e.

Substituting each occurrence of \tilde{θ} yields:

$${e}^{r} = ( {e}^{a} + ϵ {e}^{a} e ) ( \frac{s + ϵ \frac{γ}{θ} c}{θ + ϵ \frac{γ}{θ}} ( ( b + f ϵ ) i + ( c + g ϵ ) j + ( d + h ϵ ) k ) + c - ϵ \frac{γ}{θ} s ) , \\ \frac{sin \tilde{θ}}{\tilde{θ}} = \frac{s + ϵ \frac{γ}{θ} c}{θ + ϵ \frac{γ}{θ}} = \frac{( s + ϵ \frac{γ}{θ} c ) ( θ - \frac{γ}{θ} ϵ )}{( θ + \frac{γ}{θ} ϵ ) ( θ - \frac{γ}{θ} ϵ )} = \frac{θ s + ϵγ ( c - \frac{s}{θ} )}{{θ}^{2}} ,$$

Finally collecting i, j, k, ε, εi, εj, εk and representing the real and dual quaternions as vector components, respectively these are:

$${e}^{r} = ( {e}^{a} + ϵ {e}^{a} e ) [ \begin{matrix}c + \frac{s}{θ} ( bi + cj + dk ) \\ \frac{s}{θ} ( fi + gj + hk ) + \frac{γ ( c - \frac{s}{θ} )}{{θ}^{2}} ( bi + cj + dk ) - γ \frac{s}{θ}\end{matrix} ] ,$$

Substituting dual numbers into the logarithm yields:

$$\begin{matrix}\tilde{m} = \sqrt{{( a + e ϵ )}^{2} + {( b + f ϵ )}^{2} + {( c + g ϵ )}^{2} + {( d + h ϵ )}^{2}} , \\ = \sqrt{{a}^{2} + {b}^{2} + {c}^{2} + {d}^{2} + 2 ϵ ( ae + bf + cg + dh )} , \\ = \sqrt{{a}^{2} + {b}^{2} + {c}^{2} + {d}^{2}} + ϵ \frac{a e + b f + c g + d h}{\sqrt{{a}^{2} + {b}^{2} + {c}^{2} + {d}^{2}}} , \\ = {θ}^{′} + ϵ \frac{{γ}^{′}}{{θ}^{′}} ,\end{matrix}$$

$$\begin{matrix}\tilde{n} = \sqrt{{( b + f ϵ )}^{2} + {( c + g ϵ )}^{2} + {( d + h ϵ )}^{2}} , \\ = \sqrt{{b}^{2} + {c}^{2} + {d}^{2} + 2 ϵ ( bf + cg + dh )} , \\ = \sqrt{{b}^{2} + {c}^{2} + {d}^{2}} + ϵ \frac{b f + c g + d h}{\sqrt{{b}^{2} + {c}^{2} + {d}^{2}}} , \\ = θ + ϵ \frac{γ}{θ} ,\end{matrix}$$

$$\begin{matrix}\tilde{θ} = a tan 2 ( \tilde{n} , a + e ϵ ) \\ = {tan}^{- 1} \frac{( θ + ϵ \frac{γ}{θ} ) ( a - e ϵ )}{( a + e ϵ ) ( a - e ϵ )} , \\ = {tan}^{- 1} \frac{a θ + ϵ a \frac{γ}{θ} - ϵ e θ}{{a}^{2}}\end{matrix}$$

$$ln r = ln \tilde{m} + \frac{\tilde{θ}}{\tilde{n}} ( ( b + f ϵ ) i + ( c + g ϵ ) j + ( d + h ϵ ) k ) .$$

The dual number expansion of tan ⁻¹(a +βε) is:

$${tan}^{- 1} ( α + βϵ ) = {tan}^{- 1} ( α ) + \frac{β}{{α}^{2} + 1} ϵ ,$$

So then:

$$\begin{matrix}\tilde{θ} = {tan}^{- 1} \frac{a θ + ɛ a \frac{γ}{θ} - ɛ e θ}{{a}^{2}} \\ = {tan}^{- 1} ( \frac{θ}{a} ) + ( \frac{a \frac{γ}{θ} - e θ}{{a}^{2}} ) ( \frac{1}{{( \frac{θ}{a} )}^{2} + 1} ) ϵ , \\ = {tan}^{- 1} ( \frac{θ}{a} ) + \frac{a \frac{γ}{θ} - e θ}{{θ}^{2} + {a}^{2}} ϵ .\end{matrix}$$

### Setting:

$$ϕ = {tan}^{- 1} ( \frac{θ}{a} ) = a tan 2 ( θ , a ) ,$$

the dual ratio \hat{θ}/\hat{n} is:

$$\frac{\tilde{θ}}{\tilde{n}} = \frac{( ϕ + ϵ \frac{a \frac{γ}{θ} - e θ}{{θ}^{′2}} ) ( θ - ϵ \frac{γ}{θ} )}{( θ + ϵ \frac{γ}{θ} ) ( θ - ϵ \frac{γ}{θ} )} = \frac{ϕ}{θ} + ( \frac{a γ - e {θ}^{2}}{{θ}^{′ 2} {θ}^{2}} - \frac{γ ϕ}{{θ}^{3}} ) ϵ .$$

The dual number expansion of the logarithm is:

$$ln ( α + β ϵ ) = ln ( α ) + \frac{β}{α} ϵ , \\ ln \tilde{m} = ln ( {θ}^{′} + ϵ \frac{{γ}^{′}}{{θ}^{′}} ) = ln ( {θ}^{′} ) + ϵ \frac{{γ}^{′}}{{θ}^{′2}} .$$

Putting this together yields a final expression for In r, again splitting the real and dual quaternion parts:

$$ln r = [ \begin{matrix}ln ( {θ}^{′} ) + \frac{ϕ}{θ} ( bi + cj + dk ) \\ \frac{{γ}^{′}}{{θ}^{′ 2}} + \frac{ϕ}{θ} ( fi + gj + hk ) + ( \frac{a γ}{{θ}^{′2} {θ}^{2}} - ( \frac{e}{{θ}^{′2}} + \frac{γ ϕ}{{θ}^{3}} ) ) ( bi + cj + dk )\end{matrix} ] .$$

V. Hardware Acceleration of the Computation

Each complex number may be represented as a logarithm in the form:

R exp iθ=a +bi,

but crucially it can be written that:

exp(+r+i(+θ+0))=+a+bi,

exp(+r+i(+θ+π))=−a−bi,

exp(+r+i(−θ+π))=−a+bi,

exp(+r+i(−θ+0))=+a−bi,

and that:

exp(r₁+θ₁)=+a+bi,

exp(r₂+iθ₂)=+c+di,

exp(r₁+r₂+i(θ₁θ₂))=(a+bi)(c+di)

so adding together the logarithms is equivalent to multiplication, which is not the case in any quaternion or dual quaternion space due to the lack of commutativity.

As there exists hardware implementations to provide a fast method of computing a fast transformation of exp_{A}(r+iθ)=2^{r}(e^{π}/₂)^{iθ}, the above can be rewritten as:

exp _{A}(+r+i(+θ+0))=+a+bi,

exp _{A}(+r+i(+θ+2))=−a−bi,

exp _{A}(+r+i(−θ+2))=−a+bi,

exp _{A}(+r+i(−θ+0))=a−bi,

where exp _{A} denotes the affine exponentiation operation defined above, which implies modulo 4 now takes the place of modulo 2π due to the base of e^{π}/2 on the imaginary portion of the logarithm. This combined with the fact that no complex number need be separated into its components allows computations of multiplication chains to proceed in logarithmic space for as long as they are able. As many of these transforms are relatively static given the aims are generally to apply the quaternions or dual quaternions as transforms or to interpolate them, they may be transformed once into the ‘machine’ logarithmic format (not to be confused with a native quaternion or dual quaternion logarithm format) and then left as constants for much of the required computations.

For the elements of the computations that cannot be represented as whole complex number manipulations, such as the operations for which working with the quaternions and dual quaternions as complex-valued matrices would increase complexity over using their native counterparts, the exponential and logarithm capabilities of having this functionality yield methods to obtain various elementary and special functions which are helpful in the evaluation of such elements. Operations like this of particular interest are the native quaternion and dual quaternion logarithm and exponential, where although obtaining the logarithm or exponential of the equivalent complex-valued matrix may be achieved with this approach combined with an off-the-shelf method, it is not more efficient in general.

To build a machine capable of computing all of these functions efficiently for use in robotics, autonomous vehicles, gaming, solid mechanics, physics simulations or any other applications where reference frames or pose transforms must be accurately manipulated or resampled, the relatively heavy mechanism for the logarithm and exponentiation transforms must be married to a light-weight state machine for manipulating the numbers when in either format for an efficient solution.

VI. Hardware Machine Architecture

The architecture of the machine involves interleaving the slower (deep pipeline) algorithm described in previous filings, for which a logarithm or exponential mode may be selected for each individual pipeline stage allowing high throughput, with a fast (shallow pipeline) unit that computes simpler operations. By considering each pipeline stage to be operating on a separate contiguous data set, a number of data sets may be processed in parallel.

Due to the differences in pipeline depth between the two operations, register access may be optimized by interleaving reading and writing to the register file such that either the fast operations occur when the transform block is processing, partially overlaps with the transform processing or occurs after the transform processing. Placing the fast operations after the transform processing allow everything to occur in serial but incur the longest cycle time. It also allows the most separate tasks on the most separate data sets to occur in parallel in this architecture.

VII. ‘Shallow’ pipeline unit

The shallow unit requires certain operations to occur in serial to compute the multiplies in logarithm space. Since these are manipulating the signs of the real and imaginary parts and adding them, the initial set required must cover various operations such as for example, while taking:

e_{A}^{a+βi}=a+bi,

e_{A}^{X+ψi}=c+di,

describing the effect of the operation on the inputs a+βi and X+ψi yields:

| Operation description | Action result | Exponentiation |
|---|---|---|
| Unary negate | −α − βi | 1/(a + bi) |
| Binary add | α + χ + (β + ψ)i | (+a + bi)(+c + di) |
| Binary add conjugate | α + χ + (β − ψ)i | (+a + bi)(+c − di) |
| Binary add conjugate +π | α + χ + (2 + β − ψ)i | (+a + bi)(−c + di) |
| Binary add +π | α + χ + (2 + β + ψ)i | (+a + bi)(−c − di) |
| Unary increment | 1 + α + βi | 2(a + bi) |
| Unary real right bit shift | α/2 | \sqrt{∥a + bi∥} |
| Unary real left bit shift | 2α | ∥a + bi∥² |

where the +π has been converted into quadrants to take advantage of the special structure of e_{A}.

This is in addition to operations to move and copy data around. Since this is geared towards evaluating macro-operations on quaternion and dual quaternion data there are also special operations required to expedite the calculation of logarithms and exponentiations.

VIII. Limit Operations for Dual Quaternion Exponentiations and Logarithms

The exponentiation and logarithm of the dual quaternion r are:

$${e}^{r} = ( {e}^{a} + ϵ {e}^{a} e ) [ \begin{matrix}c + \frac{s}{θ} ( bi + cj + dk ) \\ \frac{s}{θ} ( fi + gj + hk ) + γ \frac{c - \frac{s}{θ}}{{θ}^{2}} ( bi + cj + dk ) - γ \frac{s}{θ}\end{matrix} ] , \\ ln r = [ \begin{matrix}ln ( {θ}^{′} ) + \frac{ϕ}{θ} ( bi + cj + dk ) \\ \frac{{γ}^{′}}{{θ}^{′ 2}} + \frac{ϕ}{θ} ( fi + gj + hk ) + ( \frac{a γ}{{θ}^{′2} {θ}^{2}} - ( \frac{e}{{θ}^{′2}} + \frac{γ ϕ}{{θ}^{3}} ) ) ( bi + cj + dk )\end{matrix} ] .$$

Many of these involve a ratio of various quantities with θ, which become increasing difficult to compute as θ tends to zero. For this reason, it is necessary to compute these ratios using a separate method that treats the limit as θ tends to zero correctly. However, to begin, the trigonometric ratio functions necessary must be isolated from the terms that are simple to compute.

The most obvious of these terms is the sinc function. The sinc function is the sine function divided by the angle:

$$sin c θ = \frac{sin θ}{θ} ,$$

and so being a ratio with a trigonometric function is a clear candidate for isolation.

This can be used to evaluate the s/θ terms from the exponentiation and the reciprocal ϕ/θ from the logarithm, because here θ=sin ϕ, and so ϕ/θ=ϕ/sin ϕ.

The next function to parameterize is in the logarithm and also fairly straight-forward:

$$\frac{c - \frac{s}{θ}}{{θ}^{2}} = \frac{cos θ - \frac{sin θ}{θ}}{{θ}^{2}} .$$

The third function that requires parameterization is more difficult and comes from the exponentiation. It is necessary to rewrite the term:

$$\begin{matrix}\frac{a γ}{{θ}^{{ }^{′2}} {θ}^{2}} - ( \frac{e}{{θ}^{{ }^{′2}}} + \frac{γ ϕ}{{θ}^{3}} ) = - \frac{e}{{θ}^{{ }^{′2}}} + γ ( \frac{a}{{θ}^{{ }^{′2}} {θ}^{2}} - \frac{ϕ}{{θ}^{3}} ) , \\ = - \frac{e}{{θ}^{{ }^{′2}}} + \frac{γ}{{θ}^{{ }^{′3}}} ( \frac{a}{{θ}^{′}} \frac{{θ}^{{r}^{2}}}{{θ}^{2}} - \frac{{ϕθ}^{{ }^{′3}}}{{θ}^{3}} ) ,\end{matrix}$$

### Since:

$$sin ϕ = \frac{θ}{{θ}^{′}} , \\ cos ϕ = \frac{a}{{θ}^{′}} ,$$

This term is then:

$$- \frac{e}{{θ}^{{ }^{′2}}} + \frac{γ}{{θ}^{{ }^{′3}}} ( \frac{cos ϕ}{{sin}^{2} ϕ} - \frac{ϕ}{{sin}^{3} ϕ} ) .$$

So the final part of this term:

$$\frac{cos ϕ}{{sin}^{2} ϕ} - \frac{ϕ}{{sin}^{3} ϕ} ,$$

is now the third function. For each of these lookup functions, the values as the independent variable tends to zero may be generated via a standard Taylor expansion around zero.

To better match the hardware available, each ln(θ′) and factor of e^{a} may be switched out for log₂ θ′ and 2^{a} respectively, without loss of generality, to make the real part of the logarithm better match the special function e_{A}, but would make the definition not directly compatible with base-e in the quaternion or dual quaternion logarithm and exponentiation. It is also possible to achieve this for the imaginary part by expand the trigonometry functions in terms of rotations or quadrants instead of radians by going back to and rewriting the angle definition of the quaternion logarithm by explicitly writing the angle as a number of rotations multiplied by 2π. Then, while considering that the logarithm and exponentiation must be inverses and respect the properties of the transform, these extraneous factors of π may be cancelled ax. This would result in a marginally cleaner derivation of these functions, if more involved, and would result in different cancellations around the bare angle in these functions. For brevity and an expeditious implementation, the worked expansions quoted here have omitted this possible permutation.

IX. Piecewise-Polynomial Interpolant Lookup Tables for (Trigonometric) Functions

As all three of the lookup functions required are even functions only the positive half of each has to be modelled. Further, it is assumed that converting between rotations and radians is handled, so the interval [0, π] in radians is mapped to the interval [0, 1].

Each [0, 1] interval is split into 2ⁿ intervals. Then for each interval [2⁻ⁿμ, 2⁻ⁿ(μ+1)] where μ is some integer [0, 2ⁿ], the interval is rescaled to [0, 1]. However, due to the scaling of the interval, the Taylor expansion may be used while keeping the interval scaling coefficient h to produce:

$$f ( x + \frac{0}{2} h ) = f ( x ) , \\ f ( x + \frac{1}{2} h ) = f ( x ) + \frac{{f}^{′} ( x )}{1 !} ( \frac{1}{2} h ) + \frac{{f}^{″} ( x )}{2 !} {( \frac{1}{2} h )}^{2} + O ( {h}^{2} ) , \\ f ( x + \frac{2}{2} h ) = f ( x ) + \frac{{f}^{′} ( x )}{1 !} ( \frac{2}{2} h ) + \frac{{f}^{″} ( x )}{2 !} {( \frac{2}{2} h )}^{2} + O ( {h}^{2} ) .$$

Rewriting these Taylor series as a matrix yields:

$$[ \begin{matrix}1 & 0 & 0 \\ 1 & \frac{1}{2} h & \frac{1}{4} {h}^{2} \\ 1 & h & {h}^{2}\end{matrix} ] [ \begin{matrix}f ( x ) \\ {f}^{′} ( x ) \\ {f}^{″} ( x )\end{matrix} ] = [ \begin{matrix}f ( x + \frac{0}{2} h ) \\ f ( x + \frac{1}{2} h ) \\ f ( x + \frac{2}{2} h )\end{matrix} ] ,$$

then inverting the Taylor series to show:

$$[ \begin{matrix}f ( x ) \\ {f}^{′} ( x ) \\ {f}^{″} ( x )\end{matrix} ] = [ \begin{matrix}1 & 0 & 0 \\ - \frac{3}{h} & \frac{4}{h} & - \frac{1}{h} \\ \frac{2}{{h}^{2}} & - \frac{4}{{h}^{2}} & \frac{2}{{h}^{2}}\end{matrix} ] [ \begin{matrix}f ( x + \frac{0}{2} h ) \\ f ( x + \frac{1}{2} h ) \\ f ( x + \frac{2}{2} h )\end{matrix} ] .$$

This then shows how f′(x) and f″(x) scale when the function values stay the same, but the interval distances change.

An interpolant with a Lagrange basis may be computed as:

$$\tilde{f} ( x ) = {f}^{'} ( \frac{0}{2} ) \cdot \frac{x - \frac{1}{2}}{\frac{0}{2} - \frac{1}{2}} \cdot \frac{x - \frac{2}{2}}{\frac{0}{2} - \frac{2}{2}} + \frac{x - \frac{1}{2}}{\frac{1}{2} - \frac{0}{2}} \cdot {f}^{'} ( \frac{1}{2} ) \cdot \frac{x - \frac{2}{2}}{\frac{1}{2} - \frac{2}{2}} + \frac{x - \frac{0}{2}}{\frac{2}{2} - \frac{0}{2}} \cdot \frac{x - \frac{1}{2}}{\frac{2}{2} - \frac{1}{2}} \cdot {f}^{'} ( \frac{2}{2} ) ,$$

and collecting terms in x yields a similar form to the inverted Taylor series matrix:

$$\tilde{f} ( x ) = {f}^{'} ( \frac{0}{2} ) + ( - 3 {f}^{'} ( \frac{0}{2} ) + 4 {f}^{'} ( \frac{1}{2} ) - {f}^{'} ( \frac{2}{2} ) ) x + ( 2 {f}^{'} ( \frac{0}{2} ) = 4 {f}^{'} ( \frac{1}{2} ) + 2 {f}^{'} ( \frac{2}{2} ) ) {x}^{2} .$$

But crucially, the rescaling of the interval from a length of 2⁻ⁿ to a length of 1, is a scale up of the h factor by 2ⁿ while keeping the values of the function the same, so this effectively multiplies a factor of 2ⁿ with the first derivative which by the Taylor series is the coefficient of x above, as can be seen from the inverse of the Taylor series matrix. A factor of 2⁻²n is effectively multiplied by the second derivative which is also the coefficient of x² above similarly shown in the inverted Taylor series matrix.

This reduces the number of bits required to represent each value to a given accuracy, allowing the use of reduced bit-width multipliers and reduced bit depth lookup tables when evaluating each term of the polynomial interpolation.

Since these functions are trigonometric in nature, their derivatives are tightly bounded, meaning that even as the multipliers become smaller, the accuracy remains constant. If it is assumed for illustration that all function evaluations, first derivatives and second derivatives are in the desired range and so evaluate to values in the range [0, 1], then the function can be described to roughly 3n-bits of accuracy using one n×n multiplier for the x² and one 2n×2n multiplier for the x term when coupled with the standard approach to evaluating polynomials through Horner's method.

This is then:

result=s0x1×(s1+x2s2),

where result is the result is to roughly 3n-bits of accuracy, s0 is the constant term to 3n-bits of accuracy, x1 is the independent variable of the interpolation required to 2n-bits of accuracy, s1 is the linear term requiring 2n-bits of storage (because it is shifted down, it is actually 3n-bits of accuracy), x2 is a further copy of the independent variable of the interpolation but only required to n-bits of accuracy and s2 is the quadratic term requiring n-bits of storage (because it is shifted down, it is actually 3n-bits of accuracy). This can then be stored as three tables of varying bit depth, each with 2ⁿ table elements. This same approach also can be extended to higher powers using more tables or the quadratic table may be cut to yield a linear approximation. This may then be extended to more accuracy using either more tables or more table elements.

However, for this scheme to be most effective, the function evaluations, first derivatives and second derivatives of the function desired to be approximated must in the desired range evaluate to values in the range [0, 1]. Any deviation from this causes the result to shed accuracy as more bits are necessary and cannot be devoted to accurate results.

This approach may be readily extended to provide lookup tables for many functions, often requiring range reduction by bit shifting, including square root, reciprocal, reciprocal square root, among others.

This approach is ideal for FPGA architectures where multiplication units are fixed sizes and scarce, while lookup tables are plentiful. This is also beneficial, especially in this implementation where because the ‘shallow’ pipeline unit requires a fast turnaround for results, the tables may be dynamically switched out between cycles to allow the function to be approximated to be selected on demand and on a per-pipeline step basis.

X. Building trigonometric lookup tables for the ‘shallow’ pipeline unit

This design has elected to merge the quadratic lookup tables into the shallow pipeline unit alongside the very simple operations described.

To create a table for the first function sin(x)/x to manipulate this into the range [0, 1], this is restructured as:

$${t}_{1} ( x ) = \frac{sin ( π x )}{π x} . \qquad ( Function 1 )$$

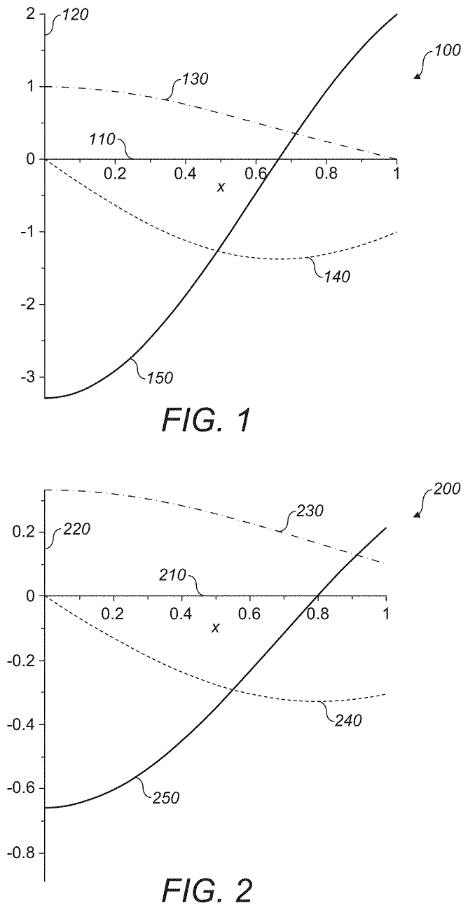

FIG. 1 shows a graph 100 of Function 1, where the x-axis 110 is x and the y-axis 120 is t₁ (x). The Function 1 plot 130 is shown as dot-dash line, its first derivative 140 is shown as a dashed line, and its second derivative 150 is shown as a solid line.

At least one bit of accuracy appears to be lost in the first derivative 140 as it is negative and has a range greater than one and three bits in the second derivative 150, as it is both positive and negative and fits within the range [−4, +4). These ranges that are too large can be bit shifted in the result, but the table and multiplies can only accept the most significant bits causing a loss of precision, seemingly of three bits (the three required to represent the integer range [−4, +4)).

The second trigonometric function is again expanded with the change of variables to take the independent variable into the range [0, 1]:

$${t}_{2} ( x ) = - \frac{cos ( π x ) - \frac{sin ( π x )}{π x}}{{π}^{2} {x}^{2}} , \qquad ( Function 2 )$$

where a negation has been applied to make the function always positive. This adds an extra bit of precision to the constant term, which is needed for maximum precision and the negation can be folded into other operations.

FIG. 2 shows a graph 200 of Function 2, where the x-axis 210 is x and the y-axis 120 is t₂(x). The Function 2 plot 230 is shown as dot-dash line, its first derivative 240 is shown as a dashed line, and its second derivative 250 is shown as a solid line. Here the first derivative curve is in the range [−0.5, +0.5) so there are no bits of precision lost even with a signed representation. However, one bit of precision is lost on the second derivative curve as its easiest fit range is [−1, +1).

The third trigonometric function is, after having changed variables to fit the interval:

$${t}_{3}^{′} ( x ) = \frac{cos ( π x )}{{sin}^{2} ( π x )} - \frac{π x}{{sin}^{3} ( π x )} , \qquad ( Function 3 )$$

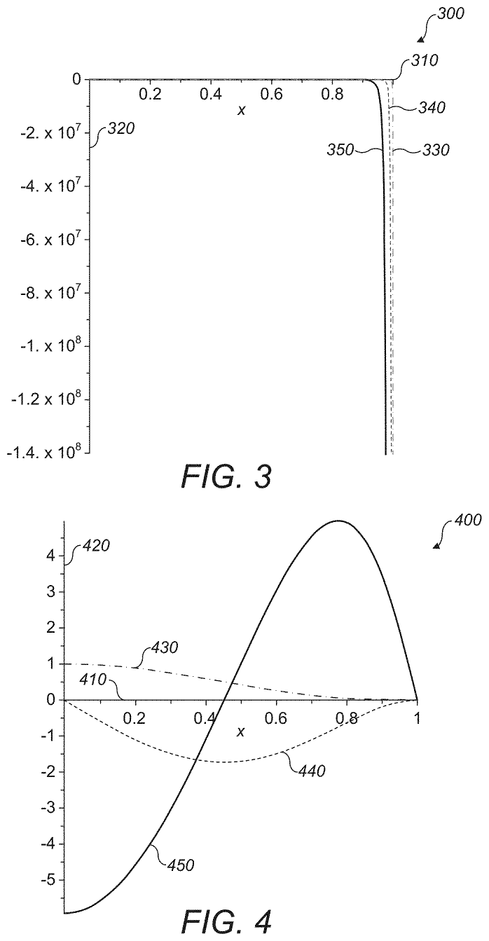

FIG. 3 shows a graph 300 of Function 3, where the x-axis 310 is x and the y-axis 320 is t₃′(x). The Function 3 plot 330 is shown as dot-dash line, its first derivative 340 is shown as a dashed line, and its second derivative 350 is shown as a solid line. All of the required function properties tend quickly to negative infinity at 1, making direct approximation difficult. This suggests that the appropriate way to handle the approximation of this function is through its reciprocal. Helpfully, the logarithm/exponentiation methods make this easily accessible. Further, to allow more bits to be gleaned from the lookup tables, a factor of ⅔ is added. Finally, the function to be approximated is:

$${t}_{3}^{′} ( x ) = - \frac{2}{3} \frac{{sin}^{2} ( πx )}{cos ( πx ) - \frac{π x}{sin ( πx )}} , \qquad ( Function 4 )$$

FIG. 4 shows a graph 400 of Function 4, where the x-axis 410 is x and the y-axis 420 is t₃′^{(x)}. The Function 4 plot 430 is shown as dot-dash line, its first derivative 440 is shown as a dashed line, and its second derivative 450 is shown as a solid line. This modified reciprocal of Function 3 is effectively the function (⅔)/((cos πx/sin² πx)−(πx/sin³ πx)).

FIG. 4 shows that Function 4 generates a function evaluation that can approximated, along with its first derivative and second derivative. This has an issue in that the second derivative loses four bits of accuracy with a range between [−8, +8), but is otherwise a functional approximation.

When the function is used, since it is taken to a logarithm before being applied as a multiplication, the logarithm form allows the −⅔ constant to be extracted and reciprocal taken as a simple additional operation to the ‘shallow’ pipeline:

| Operation description | Action result | Exponentiation |
|---|---|---|
| Constant two-thirds negate | log₂(⅔) − α | 2/(3∥a + bi∥) |

This inverts the effect of the extra changes, resulting in the logarithm of the original function t₃′(x).

A further special function for computing the conversion between revolutions and radians may be spliced with the square root function to convert more efficiently from the radians expressed in the logarithm. This is:

| Operation description | Action result | Exponentiation |
|---|---|---|
| Square root and subtract 2π | (a/2) − log₂(2π) | \sqrt{∥a + bi∥}/(2π) |

Taken together these span the methods needed.

XI. Conclusion

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

Moreover, in this document, relational terms such as first and second, top and bottom, and the like may be used solely to distinguish one entity or action from another entity or action without necessarily requiring or implying any actual such relationship or order between such entities or actions. The terms “comprises, ” “comprising, ” “has”, “having, ” “includes”, “including, ” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art. The term “coupled” as used herein is defined as connected, although not necessarily directly and not necessarily mechanically. A device or structure that is “configured” in a certain way is configured in at least that way but may also be configured in ways that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

I claim:

1. A device comprising:
a first interface that accepts at least one sample of a state of a chain of at least one rigid body transformation represented as a dual quatemion annotated with a first set of specific sampled points in time;
a second interface that accepts a second set containing at least one of the specific sampled points in time;
wherein an output of the device contains a rigid body transformation chain of the first interface resampled at the second set containing at least one of the specific sampled points in time.

2. The device of claim 1 wherein each of the rigid body transform chains is associated with a subset of the first set of specific sampled points in time.

3. The device of claim 2 wherein a parallel data pipeline is used to resample the dual quatemion transformations.

4. The device of claim 2 wherein a scalar complex-valued data pipeline is used to resample the dual quatemion transformations.

5. The device of claim 2 wherein at least one transformation is a chain provided by a tracking device synchronized to a different clock.

6. A device comprising:
a first interface that accepts a chain of at least one rigid body transformations represented as dual quaternions;
a second interface that accepts at least one of three-dimensional vectors;
wherein an output of the device contains a set of the at least one of three-dimensional vectors having been transformed by a rigid body transformation chain of the first interface.

7. The device of claim 6 wherein a parallel data pipeline is used to apply a transformation to at least one direction vector.

8. The device of claim 6 wherein a parallel data pipeline is used to apply a transformation to at least one position vector.

9. The device of claim 6 wherein a scalar complex-valued data pipeline is used to apply a transformation to at least one direction vector.

10. The device of claim 6 wherein a scalar complex-valued data pipeline is used to apply a transformation to at least one position vector.

11. A device comprising:
a first interface that accepts at least one sample of a state of a chain of at least one rigid body transformation represented as dual quaternions annotated with a first set of specific sampled points in time;
a second interface that delivers a synchronous stream of three-dimensional vector data, wherein at least one of the three-dimensional vectors is associated with a discrete synchronous point in time;
wherein an output of the device contains the synchronous stream of the second interface transformed by the at least one rigid body transformation chain of the first interface resampled at a time of the synchronous stream.

12. The device of claim 11 wherein each transform in the chain is associated with a subset of a first set of specific sampled points in time.

13. The device of claim 12 wherein at least one transformation chain is provided by a tracking device synchronized to a different clock.

14. The device of claim 12 wherein a parallel data pipeline is used to apply the transformation to at least one direction vector.

15. The device of claim 12 wherein a parallel data pipeline is used to apply the transformation to at least one position vector.

16. The device of claim 12 wherein a scalar complex-valued data pipeline is used to apply the transformation to at least one direction vector.

17. The device of claim 12 wherein a scalar complex-valued data pipeline is used to apply the transformation to at least one position vector.
